(19) United States
(12) Patent Application Publication
(10) Pub. No.: US 2014/0273530 A1
(43) Pub. Date: Sep. 18, 2014

(54) Post-Deposition Treatment Methods For Silicon Nitride

(71) Applicants: Victor Nguyen, Novato, CA (US); Isabelita Roflox, Union City, CA (US); Mihaela Balseanu, Sunnyvale, CA (US); Li-Qun Xia, Cupertino, CA (US); Heng Pan, Santa Clara, CA (US); Wei Liu, San Jose, CA (US); Malcolm J. Bevan, Santa Clara, CA (US); Christopher S. Olsen, Fremont, CA (US); Johanes F. Swenberg, Los Gatos, CA (US)

(72) Inventors: Victor Nguyen, Novato, CA (US); Isabelita Roflox, Union City, CA (US); Mihaela Balseanu, Sunnyvale, CA (US); Li-Qun Xia, Cupertino, CA (US); Heng Pan, Santa Clara, CA (US); Wei Liu, San Jose, CA (US); Malcolm J. Bevan, Santa Clara, CA (US); Christopher S. Olsen, Fremont, CA (US); Johanes F. Swenberg, Los Gatos, CA (US)

(21) Appl. No.: 14/212,425

(22) Filed: Mar. 14, 2014

Related U.S. Application Data
(60) Provisional application No. 61/787,271, filed on Mar. 15, 2013.
(60) Provisional application No. 61/789,529, filed on Mar. 15, 2013.

(51) Int. Cl. H01L 21/02

(52) U.S. Cl. CPC H01L 21/0217; H01L 21/02274
USPC 438/792

(57) ABSTRACT

Provided are methods post deposition treatment of films comprising SiN. Certain methods pertain to providing a film comprising SiN; and exposing the film to an inductively coupled plasma, capacitively coupled plasma or a microwave plasma to provide a treated film with a modulated film stress and/or wet etch rate in dilute HF. Certain other methods comprise depositing a PEALD SiN film followed by exposure to a plasma nitridation process or a UV treatment to provide a treated film.

### CROSS REFERENCE TO RELATED APPLICATIONS

This application claims priority to U.S. Provisional Application Nos. 61/787,271, filed Mar. 15, 2013 and 61/789,529, filed Mar. 15, 2013, the entire contents of both of which are herein incorporated by reference.

### TECHNICAL FIELD

The present invention relates generally to methods of post-deposition treatment methods of thin films. In particular, the invention relates to post-deposition treatment methods of SiN films.

### BACKGROUND

In the manufacture of electronic devices such as integrated circuits, a target substrate, such as a semiconductor wafer, is subjected to various processes, such as film formation, etching, oxidation, diffusion, reformation, annealing, and natural oxide film removal. Silicon-containing films are an important part of many of these processes, including silicon nitride (SiN).

Silicon nitride films have very good oxidation resistance and dielectric qualities. Accordingly, these films have been used in many applications, including oxide/nitride/oxide stacks, etch stops, oxygen diffusion barriers, and gate insulation layers, among others. Conformal coverage with low pattern loading effect of dielectric films on high aspect ratio structures are of critical requirement as device node shrinks down to below 45 nm.

As circuit geometries shrink to smaller feature sizes, thinner films with better coverage on high aspect ratio structures are required. As device technology advances, metallization schemes also are more sophisticated and require lower thermal stresses. Therefore, better quality SiN films are desired.

One method of enhancing transistor performance, the atomic lattice of a deposited material is stressed to improve the electrical properties of the material itself, or of underlying or overlying material that is strained by the force applied by a stressed deposited material. Lattice strain can increase the carrier mobility of semiconductors, such as silicon, thereby increasing the saturation current of the doped silicon transistors to thereby improve their performance. For example, localized lattice strain can be induced in the channel region of the transistor by the deposition of component materials of the transistor which have internal compressive or tensile stresses. For example, silicon nitride materials used as etch stop materials and spacers for the silicide materials of a gate electrode can be deposited as stressed materials which induce a strain in the channel region of a transistor. The type of stress desirable in the deposited material depends upon the nature of the material being stressed. For example, in CMOS device fabrication, negative-channel (NMOS) doped regions are covered with a tensile stressed material having positive tensile stress; whereas positive channel MOS (PMOS) doped regions are covered with a compressive stressed material having negative stress values.

Thus, it is desirable to form stressed materials that have predetermined types of stresses, such as tensile or compressive stresses. It is further desirable to control the level of stress generated in the deposited material. It is also desirable to deposit such stressed materials to generate uniform localized stresses or strains in the substrate. It is also desirable to have a process that can form stressed materials over active or passive devices on the substrate without damaging the devices. It is still further desirable that the deposited films be highly conformal to underlying topography.

### SUMMARY

One aspect of the invention pertains to a method of treating a film comprising SiN. The method comprises providing a film comprising SiN; and exposing the film to an inductively coupled plasma, capacitively coupled plasma or a microwave plasma to provide a treated film with a modulated film stress and/or wet etch rate in dilute HF.

In one or more embodiments, the inductively coupled plasma comprises decoupled plasma nitridation. In some embodiments, the substrate has a temperature of about 300 to about 400° C. In one or more embodiments, the chamber pressure ranges from about 4 to about 6 Torr. In some embodiments, the plasma has a power of about 100 to about 400 W. In one or more embodiments, the plasma has a frequency of about 13.5 MHz. In some embodiments, the film has a thickness of about 10 to about 40 Angstroms. In one or more embodiments, the method further comprises depositing an additional SiN layer over the treated film. In some embodiments, the additional SiN layer has a thickness of about 10 to about 40 Angstroms. In one or more embodiments, the method further comprises exposing the additional SiN layer to a plasma nitridation process.

Another aspect of the invention pertains to a method of plasma enhanced atomic layer deposition of a film comprising SiN. The method comprises exposing a substrate surface to a silicon precursor to provide a silicon precursor at the substrate surface; purging excess silicon precursor; exposing the substrate surface to an ionized reducing agent comprising a nitrogen precursor; purging excess ionized reducing agent to provide a film comprising SiN, wherein the substrate has a temperature of 23° C. to about 550° C.; and exposing the film comprising SiN to a plasma nitridation process or a UV treatment to provide a treated film.

In some embodiments, the film comprising SiN is exposed to a plasma nitridation process, the plasma nitridation process comprising decoupled plasma nitridation. In one or more embodiments, the method further comprises depositing an additional SiN layer over the treated film. In some embodiments, the additional SiN layer has a thickness of about 10 to about 40 Angstroms. In one or more embodiments, the method further comprises exposing the additional SiN layer to a plasma nitridation process. In some embodiments, the film comprising SiN is exposed to a UV treatment, and the film comprising SiN has a thickness of about 100 to about 200 Angstroms. In one or more embodiments, the method further comprises depositing an additional SiN layer over the treated film. In some embodiments, the additional SiN layer has a thickness of about 100 to about 200 Angstroms. In one or more embodiments, the method further comprises exposing the additional SiN layer to a plasma nitridation process.

Another aspect of the invention relates to a method of plasma enhanced atomic layer deposition of a film comprising SiN, the method comprising exposing a substrate surface to a silicon precursor to provide a silicon precursor at the substrate surface; purging excess silicon precursor; exposing the substrate surface to an ionized reducing agent comprising a nitrogen precursor; purging excess ionized reducing agent to provide a film comprising SiN, wherein the substrate has a temperature of 23° C. to about 550° C.; and exposing the film comprising SiN to a decoupled plasma nitridation process.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-B show FTIR data for a SiN film before and after a treatment in accordance with one or more embodiments of the invention;

FIGS. 2A-D show FTIR data for a SiN film before and after a treatment in accordance with one or more embodiments of the invention;

FIG. 3 is a TEM image of a film treated according to one or more embodiments of the invention;

FIG. 4 is a TEM image of a film treated according to one or more embodiments of the invention;

FIG. 5 is a TEM image of a film treated according to one or more embodiments of the invention;

FIG. 6 is a TEM image of a film treated according to one or more embodiments of the invention;

FIG. 7 is a TEM image of a film prior to HF clean;

FIG. 8 is a TEM image of a film after HF clean;

FIG. 9 is a graph showing the thickness of a film before and after HF clean;

FIG. 10 is a TEM image of a film treated according to one or more embodiments of the invention prior to HF clean;

FIG. 11 is a TEM image of a film treated according to one or more embodiments of the invention after HF clean;

FIG. 12 is a graph showing the thickness of a film treated according to one or more embodiments of the invention before and after HF clean; and

FIG. 13 is a graph showing the bond configuration and clean etch rate in hydrofluoric solution with different sidewall of a film treated according to one or more embodiments of the invention.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways. It is also to be understood that some chemical compounds may be illustrated herein using structural formulas which have a particular stereochemistry. These illustrations are intended as examples only and are not to be construed as limiting the disclosed structure to any particular stereochemistry. Rather, the illustrated structures are intended to encompass all such compounds having the indicated chemical formula.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention any of the film processing disclosed may also be performed on an underlayer formed on the substrate as disclosed in more detail below, and the term “substrate surface” is intended to include such underlayer as the context indicates.

It has been discovered that films comprising SiN can be treated post-deposition to engineer the films' properties. In particular, it has been discovered that stress enhancement and sidewall integrity post-HF solution clean can be improved.

It has also been discovered that highly conformal films comprising SiN can be deposited using a plasma-enhanced atomic layer deposition (PEALD) process. Such a process includes a silicon precursor, plasma reducing agent. In one or more embodiments, the processed described herein deposit low pattern loading, conformal nitride films by PEALD as spacer and etch stop layers in memory and logic process flow. One or more embodiments advantageously allow for low temperature processing (including well below 550° C.). Such temperatures are particularly suitable for high-k dielectric processing. Another benefit of one or more of the processes described herein is the capability of tailoring conformal films to desired composition and properties. The properties of the films can be tuned by using one or a combination of the methods described below, including post-treatment using plasma and/or ultraviolet (UV) cure.

In some embodiments, post-deposition treatment methods may be utilized to engineer the film properties, particularly stress enhancement. As used herein, “post-deposition” means that the treatment is carried out after at least some amount of film has been deposited or, as the specific situation calls for, one PEALD cycle. In some embodiments, the treatment process is carried out at certain film thickness intervals and/or cycles, and in other embodiments, the treatment process is carried out once deposition is completed.

### Plasma Treatment

Accordingly, a first aspect of the invention pertains to a method of treating a film comprising SiN. The method comprises providing a film comprising SiN; and exposing the film to an inductively coupled plasma, capacitively coupled plasma or a microwave plasma to modulate film stress and/or wet etch rate in HF solution clean.

In one or more embodiments, the plasma treatment allows for the film stress to be modulated from about 0.5 GPa to about −1.5 GPa compressive. The wet etch rate in HF can also be improved to levels similar to that of thermal oxides.

The nitridation process plasma can be created from gases such as Ar, He, NH₃, N₂, H₂ or combinations thereof. While not wishing to be bound to any particular theory, it is though that the plasma treatment can remove H— from SiH— and NH— bonds to create SiN bonds and/or increase the density of the ALD film. Ar, Ar/H2, and Ar/N2 plasma all remove H from as-deposited film seen with reduction in peak areas of SiH and NH. The advantage of plasma treatment is the removal amount and SiH/NH selectivity both can be controlled with different plasma gases. In addition, plasma treatment has more degrees of control with chamber conditions such as coupling power, pressure and gas flows. Other parameters in tuning final film properties include the thickness of each treated layer and type of plasma (direct vs. remote sources; inductively coupling vs. capacitive coupling).

Although previous methods have been utilized for increasing the tensile strength, the methods described herein differ as they focused on in-situ treatment, and remove hydrogen film. In-situ treatment is often accomplished with a parallel-plated low density plasma environment similar to that of plasma deposition. The enhancement effect is highly dependent on the vertical ions flux and energy that bombard the surface. As the technology advances at smaller nodes, devices get taller and the separation between adjacent devices is smaller. Therefore, film deposition on the sidewall does not receive the same ion dose as on the structure's top or bottom. In contrast, the methods described herein are highly uniform. This allows for a uniform treatment, such that the sidewall is similar to the top of the structure. This allows for the film properties to be similar throughout the structure. However, film engineering capabilities is still preserved with different plasma type.

In one or more embodiments, the plasma treatment is performed during the deposition of the dielectric film(s) on structures (“insitu treatment”) as well as the post deposition treatments to strengthen (for example to reduce WER) on the sidewall.

In some embodiments, the plasma is a capacitively coupled plasma (CCP), inductively coupled plasma (ICP), or microwave plasma. The ICP power may range from about 100-2000 W at 13.56 MHz. In one or more embodiments, the plasma type includes decoupled plasma nitridation (DPN). DPN is a plasma method that uses inductive coupling to generate nitrogen plasma and incorporate nitrogen into the top surface layer of an ultra-thin gate oxide to increase the dielectric constant of the gate dielectric. The DPN may be operated with the following conditions: about 20 mT-80 mT, RF power about 100-2000 W, and flow rate about 100 sccm-2000 sccm.

The plasma may be either continuous or pulsed. Pulsing the plasma may minimize charge damage. The specific plasma chemistry may be selected according to the specific dielectric film being treated. For example, a SiN film may be treated with Ar or Ar/N₂ plasma.

In spatial ALD, both the first and second precursors are simultaneously flowed to the chamber but are separated spatially so that there is a region between the flows that prevents mixing of the precursors. In spatial ALD, the substrate must be moved relative to the gas distribution plate, or vice-versa. In such an arrangement, one or more of the injector channels can have plasma or other energy source (i.e., UV or heating).

Process conditions may vary depending on the specific film treated. However, in embodiments using CCP or ICP (e.g., DPN), the following conditions may be used as a guideline. In one or more embodiments, the substrate surface will have a temperature of about 20 to about 550° C. In further embodiments, the temperature will be about 300 to about 400° C. In one or more embodiments, the N₂ precursor may be flowed at a rate of about 1 to about 25,000 sccm. In further embodiments, the flow rate may be about 500 to about 1000 sccm. In some embodiments, Ar dilution gas may be flowed at a rate of about 1 of about 25,000. In further embodiments, the flow rate may be about 4,000 to about 5,000. In one or more embodiments, chamber pressure may range from about 10⁻⁴ to about 10 Torr. In further embodiments, the pressure ranges from about 4 Torr to about 6 Torr. In some embodiments, the plasma power may range from 10 W to about 1 kW. In further embodiments, the plasma power may range from about 50, 100, 200 or 250 W to about 300, 350, or 400 W. In one or more embodiments, the plasma frequency may be 350 kHZ, 60 MHz or microwave. In further embodiments, the plasma frequency may be 13.5 MHz. In some embodiments, the plasma pulse length may range from about 1 to about 100%. In further embodiments, the plasma pulse length is 100%. In one or more embodiments, the plasma pulse frequency ranges from about 1 to about 10⁴. In further embodiments, the plasma pulse frequency is about 1. In some embodiments, the plasma exposure time ranges from about 1 second to about 600 seconds. In further embodiments, the plasma exposure time ranges from about 5 to about 100 seconds, or about 10 to about 80 seconds, or in further embodiments, about 15 seconds.

In one or more embodiments, post-deposition treatment may require avoiding a vacuum break between deposition and treatment. There may thus be a need to have multiple chambers on the same tool. In some embodiments, the post-deposition treatment is carried out without a vacuum break after deposition of the film. This will help to avoid oxidation of the conformal film.

In one or more embodiments, the treatment effectiveness may be dependent on the penetration depth of active species. That is, the treatment may be applied once every time a set number of deposition cycles or thickness has been deposited. For example, a treatment may be carried out every ALD deposition cycle, and/or after a certain number of Angstroms have been deposited.

In some embodiments, the plasma treatment may be applied on a film have a thickness ranging from about 10 to about 500 Angstroms. In further embodiments, the thickness ranges from about 10 to about 40 Angstroms. In even further embodiments, the thickness is about 20 Angstroms. In some embodiments, more film (e.g. additional SiN film) is deposited over the treated film. In further embodiments, another 10 to 500 Angstroms is deposited and again treated. This process may be repeated until the overall desired film thickness has been achieved.

### Post-Treatment of PEALD SiN Film

Another aspect of the invention pertains to plasma and/or UV post-deposition treatment processes of plasma-enhanced atomic layer deposition (PEALD) SiN. Accordingly, one aspect of the invention relates to a method of plasma enhanced atomic layer deposition of a film comprising SiN. The method comprises exposing a substrate surface to a silicon precursor to saturate the substrate surface with silicon species (i.e., to provide a silicon precursor at the substrate surface); purging excess silicon precursor; exposing the substrate surface to an ionized reducing agent comprising a nitrogen precursor; and purging excess ionized reducing agent to provide a film comprising SiN, wherein the substrate has a temperature of 23° C. to about 550° C. In some embodiments, the method comprises exposing a substrate surface to a precursor comprising silicon and nitrogen to provide a precursor comprising silicon and nitrogen at the substrate surface; purging excess precursor; exposing the substrate surface to an ionized reducing agent; and purging excess ionized reducing agent to provide a film comprising SiN, wherein the substrate has a temperature of 23° C. to about 550° C. In one or more embodiments, “to provide a precursor at the substrate surface” means that the silicon precursor saturates the substrate surface with a layer of the silicon precursor's reacting species.

As used herein, “SiN” refers to a deposited film that comprises Si—N bond linkages. In some embodiments, the film may be represented by the formula Si₃Nₓ, where x is equal to about 4. It will be understood that the variable x may vary depending on the specific precursors chosen, including the initial ratio of silicon to carbon in the precursors.

In the first part of the ALD cycle, a substrate surface is exposed to a silicon precursor. In some embodiments, exposure to the silicon precursor results in the silicon precursor reacting with the surface. In one or more embodiments, the silicon precursor may be a halogenated silane. That is, in some embodiments, the silicon precursor comprises a Si—X bond, wherein X is a halogen. In further embodiments, the silicon precursor comprises SiH_{4-y}X_{y} or X_{3-z}H_{z}Si—SiH_{z}X_{3-z}, wherein X is a halide selected from the group consisting of Cl, Br and I, y has a value of 1 to 4, and z has a value of 0 to 2. In some embodiments, the first precursor comprises SiX₄. In other embodiments, the first precursor comprises X₃Si—SiX₃. In one or more embodiments, each X is independently selected from Cl, Br and I. In further embodiments, embodiments at least one of the X groups is Cl. Examples of such halogenated silanes include, but are not limited to, hexachlorodisilane (HCDS), monochorosilane, and dichlorosilane (DCS). In even further embodiments, all X groups are Cl. In embodiments where the first precursor comprises X₃Si—SiX₃, and all X groups are chlorine, the compound is Cl₃Si—SiCl₃, also known as hexachlorodisilane. Accordingly, in one or more embodiments, the silicon precursor is selected from SiCl₄, SiBr₄, or SiLₜ.

In one or more embodiments, the silicon precursor may also comprise carbon. Such examples include alkyl halogenated silanes, which may have formula (X_{y}H_{3-y}Si)_{z}CH_{4-z}. In one or more embodiments, each X is independently selected from Cl, Br and I. In further embodiments, embodiments at least one of the X groups is Cl. In even further embodiments, all X groups are Cl. Such a compound is known as bis(trichlorosilyl)methane (BTCSM), hexachlorodisilylmethylene (HCDSM), 1,1′-methylenebis(1,1,1-trichlorosilane), or methylenebis(trichlorosilane), and has a structure represented by:

[chemical structure]

Other examples of suitable precursors include, but are not limited to those having a structure represented by:

[chemical structure]

In other embodiments, the first precursor has a formula (X_{y}H_{3-y} Si)(CH₂)ₙ(SiX_{y}H_{3-y}). In further embodiments, n has a value of 2 or 3, or in even further embodiments, 2. Compounds of this formula may be used to further increase the carbon content, as the starting C:Si ratio will be higher. In one or more embodiments, each X is independently selected from Cl, Br and I. In further embodiments, embodiments at least one of the X groups is Cl. In even further embodiments, all X groups are Cl.

In yet other embodiments, the first precursor comprises (X_{y}H_{3-y}Si)(CH₂) (SiXₚH₂₋ₚ)(CH₂)(SiX_{y}H_{3-y}), wherein X is a halogen, y has a value of between 1 and 3, p has a value of between 0 and 2. In one or more embodiments, each X is independently selected from Cl, Br and I. In further embodiments, embodiments at least one of the X groups is Cl. In even further embodiments, all X groups are Cl. Examples of such precursors include, but are not limited to, (ClSiH₂)(CH₂)(SiH₂)(CH₂)(SiH₂Cl) and (Cl₂SiH)(CH₂)(SiClH)(CH₂)(SiHCl₂).

In some embodiments, the silicon precursor may also comprise nitrogen. Examples of such precursors include amine-halogenated silanes, which also contain both silicon and nitrogen atoms. Examples of such compounds include, but are not limited to trisylylamine (TSA) and bis-diethylamine silane (BDEAS). Other examples of silicon precursors also containing nitrogen include silazane-based precursors. Such compounds have the formula:

[chemical structure]

wherein each R is independently hydrogen or C1-C6 alkyl. In some embodiments, at least one of the R groups is methyl. In further embodiments, the silicon precursor is silazane. In other embodiments, the silicon precursor has formula (SiH₃)₂NH. It should be noted that where the R group contains carbon, the resulting film may contain carbon as well.

Suitable process flow rates will depend on the specific precursor chosen. However, generally, where the silicon precursor is a gas, the flow rate will range from about 1 sccm to about 5000 sccm. In further embodiments, the flow rate will range from 25, 50, 75 or 100 to about 200, 250, 300, 350, 400, 500 or 600 sccm. Suitable gas flow rates for a halogenated silane precursor (e.g., dichlorosilane) may be about 100 to about 200 sccm. Generally, where the silicon precursor is a liquid, the flow rate will range from about 1 sccm to about 5000 mgm. In further embodiments, the flow rate will range from 10, 20, 30, or 50 to about 100, 125, 150, 175, 200 or 250 sccm. Suitable liquid flow rates for a halogenated silane precursor (e.g., HCDS) may be about 50 to about 100 mgm.

Once the substrate surface has been exposed to the silicon precursor, excess unreacted precursor may be removed. For example, excess silicon precursor may be pumped away, leaving behind a monolayer of atoms on all surfaces. It is thought that the reaction is self-saturating because the layer has halogen-terminated bonds. The self-saturating nature of the reaction helps to provide excellent step coverage.

Once the monolayer of atoms is provided at the substrate surface, the substrate surface may then be exposed to a reducing agent. Usually, at lower surface temperature (e.g., below 550° C.), reaction between NH₃-based gases and the layer becomes less effective. However, it has been discovered that an ionizedreducing gases by plasma greatly increases the effectiveness of the reaction due to higher energy levels. The gases can be ionized inside the chamber, or outside (i.e., remotely) then flown into the chamber. Exemplary reducing agents include, but are not limited to NH₃, H₂, and N₂. Reducing agents which contain nitrogen will act as nitrogen precursors for the film. Hydrogen can be a suitable reducing agent where the silicon precursor also contains nitrogen, and the objective is to engineer the nitrogen atomic composition in the film. Reactions of the film with these gases result in the removal of halogen atoms cross-linking to form the Si—N—Si network. The reducing gases may then be pumped or purged away.

Suitable process flow rates will depend on the specific reductant chosen. Generally, the flow rate will range from about 1 sccm to about 25000 sccm. In further embodiments, the flow rate will range from 250, 500, 750 or 1000 to about 2000, 2250, 2500 or 2750 sccm. Suitable gas flow rates for some reducing agents (e.g., NH₃) may be about 100 to about 200 sccm.

One or more of the processes described herein include a purge. The purging process keeps the reagents separate. Unwanted mixture of reagents may degrade step coverage. The substrate and chamber may be exposed to a purge step after stopping the flow of one or more of the reagents. A purge gas may be administered into the processing chamber with a flow rate within a range from about 10 sccm to about 10,000 sccm, for example, from about 50 sccm to about 5,000 sccm, and in a specific example, about 1000 sccm. The purge step removes any excess precursor, byproducts and other contaminants within the processing chamber. The purge step may be conducted for a time period within a range from about 0.1 seconds to about 60 seconds, for example, from about 1 second to about 10 seconds, and in a specific example, from about 5 seconds. The carrier gas, the purge gas, the deposition gas, or other process gas may contain nitrogen, hydrogen, argon, neon, helium, or combinations thereof. In one example, the carrier gas comprises argon and nitrogen.

The precursor and/or reducing gases may be diluted with an inert gas. Examples include noble gases and N₂. In one or more embodiments, the flow rate of an inert dilution ranges from about 1 to about 25000 sccm. In further embodiments, the flow rate will range from about 1000 to about 5000 sccm.

Chamber pressure during the deposition process may range from about 1 Torr to about 50 Torr. In further embodiments, the pressure may range from about 1 to about 15 Torr. In some embodiments, the pressure may be about 4, 5, 6, 7, 8, 9 or 10 Torr.

The above process can be repeated until a desired film thickness is achieved. Thus, following the above, the silicon precursors may be re-introduced, following by another purge, flow of ionized reducing agent, and another purge. The cyclic process continues until we achieve the targeted film thickness.

An advantage of one or more of the process described herein is that deposition can take place at relatively low temperatures. In some embodiments, the substrate surface has (deposition is carried out at) a temperature of about 20° C. to about 550° C. In one or more embodiments, the deposition is carried out at a temperature of about 50, 100, 200, 250 or 300° C. to about 400, 450 or 500° C. In some embodiments, the substrate temperature ranges from about 200 to about 400° C.

In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to 350 kHz, 13.56 MHz and 60 MHz.

Other plasma conditions may range depending on the specific process. Generally, the plasma power will range from about 1 W to about 1 kW. In further embodiments, the plasma power will be about 50, 75, 100, 125, 150, 175, 200, 300 or 400 W. Exposure time of the plasma per layer may range from about 1 second to about 60 seconds. In further embodiments, the plasma exposure time may be range from about 5 or 10 seconds to about 20, 30 or 40 seconds. In further embodiments, the plasma exposure time is about 10 seconds.

The deposited film may then be exposed to a post-deposition treatment process. In some embodiments, the post-deposition treatment is carried out without a vacuum break after deposition of the SiN film. This will help to avoid oxidation of the conformal SiN film.

In one or more embodiments, the post-deposition treatment comprises a plasma treatment. The plasma treatment may be utilized to increase the tensile strength of the film. While not wishing to be bound to any particular theory, it is thought that the tensile strength of the film is increased because the plasma removes hydrogen from the film. The plasma treatment may be carried out after the deposition of a film of a given thickness. For example, a plasma treatment may be carried out every 10 to 40 Angstroms of film deposited, or more specifically about every 20 Angstroms.

In some embodiments, the post-deposition treatment comprises treatment with ultraviolet (UV) light. An example of such a treatment is UV annealing/cure. With an UV treatment process, the tensile stress of one or more of the films described herein can be increased from 0.5 GPa to 1.3 GPa, or even higher. The UV treatment may be carried out after the deposition of a film of a given thickness. For example, a UV cure may be carried out every 50 to 500 Angstroms of film deposited, or more specifically about every 100 to 200 Angstroms.

The tensile stress of an as-deposited silicon nitride material can be further increased by treating the deposited material with exposure to ultraviolet radiation. It is believed that ultraviolet and electron beam exposure can be used to further reduce the hydrogen content in the deposited material. The energy beam exposure can be performed within the ALD chamber itself or in a separate chamber. For example, a substrate having the deposited stressed material could be exposed to ultraviolet or electron beam radiation inside the ALD processing chamber. In such an embodiment, the exposure source could be protected from the ALD reaction by a shield or by introducing the exposure source into the chamber subsequent to the flow of process gas. The ultraviolet or electron beams could be applied to the substrate, in-situ in the ALD deposition chamber during a ALD reaction to deposit the stressed material. In this version, it is believed that ultraviolet or e-beam exposure during the deposition reaction would disrupt undesirable bonds as they are formed, thereby enhancing the stress values of the deposited stressed material.

It was determined that exposure of the deposited silicon nitride material to ultraviolet radiation or electron beams is capable of reducing the hydrogen content of the deposited material, and thereby increasing the tensile stress value of the material. It is believed that exposure to ultraviolet radiation allows replacement of unwanted chemical bonds with more desirable chemical bonds. For example, the wavelength of UV radiation delivered in the exposure may be selected to disrupt unwanted hydrogen bonds, such as the Si—H and N—H bond that absorbs this wavelength. The remaining silicon atom then forms a bond with an available nitrogen atom to form the desired Si—N bonds.

The UV treatment technique has a bulk effect. The entire film can be treated at once and the process is more efficient and can break more bonds. Also, because a broadband UV source emitting wavelengths down to 200 nm is being used, the UV energy also favors re-bonding of the dangling bonds to form the strained Si—N bonds. Specifically, some dangling bonds remain during the formation of all films. These dangling bonds have the effect of degrading electrical properties of the film. These dangling bonds can survive subsequent treatment, especially if the distance between a Si dangling bond and a N dangling bond is too large. The UV treatment technique provides the necessary activation energy to allow the two types (Si and N) of dangling bonds to form a desired Si—N bond.

In one or more embodiments, the plasma treatment is performed during the deposition of the dielectric film(s) on structures (“insitu treatment”) as well as the post deposition treatments to strengthen (for example to reduce WER) on the sidewall.

Some UV cure conditions to consider include temperature, inert carrier gas dilution, pressure, UV power and UV exposure time. Exemplary process conditions will be described. In one or more embodiments the substrate temperature during UV cure ranges from about 20 to about 500° C., and in further embodiments, from about 300 to about 400° C. In some embodiments, the inert gas dilution (sccm) is about 1 L to about 50 L, and in further embodiments, about 10 L. In one or more embodiments, the chamber pressure ranges from about 1 to about 10 Torr, and in further embodiments, about 4 to about 6 Torr. In some embodiments, the UV power ranges from about 10% to about 100%. In further embodiments, the UV power is about 10%. In one or more embodiments, the UV exposure time ranges from about 1 second to about 1000 seconds, and in further embodiments, about 50 to about 150 seconds, and in even further embodiments, about 120 seconds.

In some embodiments, the UV treatment may be applied on a film have a thickness ranging from about 50 to about 500 Angstroms. In further embodiments, the thickness ranges from about 100 to about 200 Angstroms. In some embodiments, more film is deposited over the treated film. In further embodiments, another 10 to 500 Angstroms is deposited and again treated. This process may be repeated until the overall desired film thickness has been achieved.

In one or more embodiments, the UV treatment process allows for the treated film's tensile stress to be increased about 0.5 GPa to about 1.5 GPa. UV radiation provide activation energy to remove H atoms from adjacent SiH and NH molecules and form a new, more stable SiN, The shrinkage of H and formation of the new bonds result in higher tensile stress values.

Thus, in an exemplary process, the method comprises:
(a) exposing a substrate surface to a silicon precursor to provide a silicon precursor at the substrate surface;
(b) purging excess silicon precursor;
(c) exposing the substrate surface to an ionized reducing agent comprising a nitrogen precursor;
(d) purging excess ionized reducing agent to provide a film comprising SiN, wherein the substrate has a temperature of 23° C. to about 550° C.;
(e) repeating (a)-(d);
(f) exposing the film comprising SiN to a plasma treatment once about 10 to about 40 Angstroms of film have been deposited, or a UV cure once about 50 to about 500 Angstroms of film have been deposited.

The precursors/reagents may be flowed and/or exposed to the substrate surface either sequentially or substantially sequentially. The process may be repeated up until a desired film thickness has been achieved. As used herein, “substantially sequentially” refers to where a majority of the exposure/flow of a given precursor does not overlap with the flow/exposure of another precursor, although there may be some overlap.

The films resulting from one or more of the deposition processes described herein result in a film with good step coverage and conformality. One measure of conformality is the ratio of sidewall/top and bottom/top thickness ratio. Perfect conformality corresponds to a ratio of 100% (i.e., the two thicknesses are the same). In one or more embodiments, the ratios achieved by the processes described herein are greater than 95%. Another useful measurement is the pattern loading effect (PLE) is the difference in thicknesses in isolated field area versus dense area, and represents the difference between field and structure thickness. Usually, a PLE value of less than 5% is desirable. In one or more embodiments, the process described herein can provide a PLE value of less than about 5, 4, or 3%.

The specific reaction conditions for the ALD reaction will be selected based on the properties of the film precursors, substrate surface, etc. The deposition may be carried out at atmospheric pressure, but may also be carried out at reduced pressure. The substrate temperature should be low enough to keep the bonds of the substrate surface intact and to prevent thermal decomposition of gaseous reactants. However, the substrate temperature should also be high enough to keep the film precursors in the gaseous phase and to provide sufficient energy for surface reactions. The specific temperature depends on the specific substrate, film precursors, and pressure. The properties of the specific substrate, film precursors, etc. may be evaluated using methods known in the art, allowing selection of appropriate temperature and pressure for the reaction.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as rapid thermal processing (RTP), plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chamber, where a single substrate is loaded, processed and unloaded before another substrate is processed. The substrate can also be processed in a continuous manner, like a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path. As discussed above, in some embodiments, post-deposition treatment occurs in the same chamber as deposition. In one or more embodiments, UV treatment occurs in the same chamber as deposition.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

In atomic layer deposition type chambers, the substrate can be exposed to the first and second precursors either spatially or temporally separated processes. Temporal ALD is a traditional process in which the first precursor flows into the chamber to react with the surface. The first precursor is purged from the chamber before flowing the second precursor. In spatial ALD, both the first and second precursors are simultaneously flowed to the chamber but are separated spatially so that there is a region between the flows that prevents mixing of the precursors. In spatial ALD, the substrate must be moved relative to the gas distribution plate, or vice-versa.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

### EXAMPLES

### Example 1

### UV Post-Deposition Treatment

A silicon nitride film was deposited via PEALD. The substrate is heated at 400° C. in a sub-atmospheric environment. The silicon precursor of Hexachlorodisilane (HCDS) is deposited first while N-sources of NH3 and N2 are deposited sequentially in an Ar plasma. Post deposition, it was exposed to a UV anneal also at 400° C. for 5 minutes in Ar dilution at sub-atmospheric pressure. FTIR data was collected as-deposited and post-anneal, and is shown in FIGS. 1A-B. As can be seen in the figures, the peak areas at SiH (2100 cm⁻¹) and NH (3400 cm⁻¹) are reduced after UV exposure. Other film properties as-deposited and post-treatment are shown in Table 1 below.

TABLE 1

| | | | | | | Post |
|---|---|---|---|---|---|---|
| | As- | Post UV | Post Ar | Post Ar/N₂ | Post Ar/H₂ | NH₃/N₂ |
| | deposited | anneal | Plasma | Plasma | Plasma | Plasma |
| Refractive | 1.77 | 1.83 | 1.87 | 1.90 | 1.84 | 1.84 |
| Index @ | | | | | | |
| 633 nm | | | | | | |
| Stress (MPa) | 500 | 1500 | −1500 | 500 | 900 | 400 |
| WER (A/min) | 300 | 250 | 60 | 40 | 200 | 250 |

As can be seen from the table, the post-deposition treatment can modulate the original (as-deposited) film stress to be high compressive (−1500 MPa) or high tensile (1500 MPa) to be beneficial for multiple device designs. Also, the different refractive indices represent film compositions from different Si/N atomic percentage. The composition wiln addition, we can reduce the wet etch rate (WER) in HF-clean solution by an order of magnitude down to 40 A/min, similar to that of thermal oxide, a standard benchmark.

### Example 2

### Plasma Post-Deposition Treatment

A silicon nitride film was deposited via PEALD. The substrate is heated at 400° C. in a sub-atmospheric environment. The silicon precursor of Hexachlorodisilane (HCDS) is deposited first while N-sources of NH3 and N2 are deposited sequentially in Ar plasma. Post deposition, it was exposed to a 13.5 MHz plasma treatment of Ar and N2 at pressure between 20 Torr and 80 Torr for 30 s after every 20 A of deposition. The ICP power was 100-2000 W at 13.56 MHz. FTIR data was collected as-deposited and post-treatment, and is shown in FIGS. 2A-D. As can be seen in the figures, the peak areas at SiH (2100 cm⁻¹) and NH (3400 cm⁻¹) are reduced after plasma treatment, corresponding to H removal.

TEM images were taken of the film over a patterned feature to show step coverage and over a flat substrate, and are shown in FIGS. 5 and 6, respectively. The figures also show the film thickness at several different locations. As can be seen in the figures, the films are highly conformal, with little variation in the film thickness.

The step coverage and pattern loading effect are still excellent with film post treatment as seen in FIGS. 3-6. The difference in thicknesses between sidewall/bottom compared to top is 5%. The thickness difference between dense and open area is 3% for 3:1 aspect ratio small gap structure seen below.

### Example 3

### Post-Deposition UV Anneal

The same ALD SiN films were deposited using PEALD. After deposition, the film was exposed to a UV cure. The UV anneal at 400° C. for 5 minutes in Ar dilution at sub-atmospheric pressure. TEM images were taken of the film over a patterned feature to show step coverage and over a flat substrate, and are shown in FIGS. 3 and 4, respectively. The figures also show the film thickness at several different locations. As can be seen in the figures, the films are highly conformal, with little variation in the film thickness.

### Example 5

### HF Clean of Untreated Film (Comparative)

A SiN film was deposited by PECVD with SiH₄ as Si precursor and NH₃, N₂ as N sources at low power and pressure. The 80% step coverage over a very high aspect ratio structure over a patterned substrate, highlights the challenges and limits of conventional CVD deposition technique. FIG. 7 is a TEM image of the film. The film was then treated with hydrofluoric solution (HF). A TEM image of the resulting film is shown in FIG. 8. This example is considered comparative because the film was not given a post-deposition treatment.

FIG. 9 is a graph showing the film thickness prior to and after HF clean. As shown in the figure by the arrow, there is a large difference between the untreated film prior to etch (“Baseline Treat (no etch)”) and after etching (“Baseline Treat (etch)”). This demonstrates insufficient side wall treatment. The film is etched at a much faster rate at the sidewall than at the top and bottom. This is due to lower ion flux and energy arriving at the sidewall compared to at the top or bottom of the structures. Such a result is highly undesirable.

### Example 6

### HF Clean of Treated Film

The process of Example 5 was repeated, except that the film was treated by DPN. The film before HF clean is shown in FIG. 10, and after HF clean in FIG. 11. A graph showing the film thickness prior to and after HF clean is shown in FIG. 12. The figures and graph demonstrate a much improved side wall treatment. That is, the thickness on the sidewall is well-preserved.

### Example 7

### Conformal Nitride Treatment by DPN

FIG. 13 is a comparison of bond configuration and clean etch rate in HF solution with different sidewall uniformed plasma. As seen in FIGS. 11 and 12, the clean etch rate is similar on sidewall and to the top, which indicates uniform film properties. The different plasma types can be tuned by using different gas combination and conditions to have different film properties and clean etch rate. For example, if a N-rich film is beneficial to a certain device type, NH₃—Ar DPN would be chosen. On the other hand, if a more balance N/Si atom ratio is desired, N₂—Ar plasma would be chosen. Pulsing N₂—Ar plasma will also yield some processing windows.

What is claimed is:

1. A method of treating a film comprising SiN, the method comprising:
providing a film comprising SiN; and
exposing the film to an inductively coupled plasma, capacitively coupled plasma or a microwave plasma to provide a treated film with a modulated film stress and/or wet etch rate in dilute HF.

2. The method of claim 1, wherein the inductively coupled plasma comprises decoupled plasma nitridation.

3. The method of claim 1, wherein the substrate has a temperature of about 300 to about 400° C.

4. The method of claim 1, wherein the chamber pressure ranges from about 4 to about 6 Torr.

5. The method of claim 1, wherein the plasma has a power of about 100 to about 400 W.

6. The method of claim 1, wherein the plasma has a frequency of about 13.5 MHz.

7. The method of claim 1, wherein the film has a thickness of about 10 to about 40 Angstroms.

8. The method of claim 7, further comprising depositing an additional SiN layer over the treated film.

9. The method of claim 8, wherein the additional SiN layer has a thickness of about 10 to about 40 Angstroms.

10. The method of claim 9, further comprising exposing the additional SiN layer to a plasma nitridation process.

11. A method of plasma enhanced atomic layer deposition of a film comprising SiN, the method comprising:
exposing a substrate surface to a silicon precursor to provide a silicon precursor at the substrate surface;
purging excess silicon precursor;
exposing the substrate surface to an ionized reducing agent comprising a nitrogen precursor;
purging excess ionized reducing agent to provide a film comprising SiN, wherein the substrate has a temperature of 23° C. to about 550° C.; and
exposing the film comprising SiN to a plasma nitridation process or a UV treatment to provide a treated film.

12. The method of claim 11, wherein the film comprising SiN is exposed to a plasma nitridation process, the plasma nitridation process comprising decoupled plasma nitridation.

13. The method of claim 11, further comprising depositing an additional SiN layer over the treated film.

14. The method of claim 13, wherein the additional SiN layer has a thickness of about 10 to about 40 Angstroms.

15. The method of claim 14, further comprising exposing the additional SiN layer to a plasma nitridation process.

16. The method of claim 11, wherein the film comprising SiN is exposed to a UV treatment, and the film comprising SiN has a thickness of about 100 to about 200 Angstroms.

17. The method of claim 16, further comprising depositing an additional SiN layer over the treated film.

18. The method of claim 17, wherein the additional SiN layer has a thickness of about 100 to about 200 Angstroms.

19. The method of claim 18, further comprising exposing the additional SiN layer to a plasma nitridation process.

20. A method of plasma enhanced atomic layer deposition of a film comprising SiN, the method comprising:
exposing a substrate surface to a silicon precursor to provide a silicon precursor at the substrate surface;
purging excess silicon precursor;
exposing the substrate surface to an ionized reducing agent comprising a nitrogen precursor;
purging excess ionized reducing agent to provide a film comprising SiN, wherein the substrate has a temperature of 23° C. to about 550° C.; and
exposing the film comprising SiN to a decoupled plasma nitridation process.
